(19) United States
(12) Patent Application Publication
(10) Pub. No.: US 2007/0155025 A1
(43) Pub. Date: Jul. 5, 2007

(54) Nanowire structures and devices for use in large-area electronics and methods of making the same

(76) Inventors: Anping Zhang, Niskayuna, NY (US); Yun Li, Niskayuna, NY (US); Thomas Paul Feist, Niskayna, NY (US); William Hullinger Huber, Scotia, NY (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 11/325,026

(22) Filed: Jan. 4, 2006

(51) Int. Cl. H01L 21/36

(52) U.S. Cl. 438/3; 438/680; 438/478; 977/762; 257/421

(57) ABSTRACT

A nanowire structure and device for use in large area electronics and methods of making the same is provided. The nanowire structure includes a nanowire defining an axis, where the nanowire includes a first end and a second end. The first end is axially spaced from the second end. Further, the nanowire structure includes magnetic segments that are coupled to the first and second ends of the nanowire.

### BACKGROUND

The invention relates generally to the field of large-area electronics on flexible or rigid substrate, and more particularly to the large-area flexible electronics enabled by nanowire structures and methods of making the same.

Although rapid miniaturization of microelectronics has led to cost reduction, integration of these devices over large area substrates still poses challenges in terms of device efficiency and reliability. Current large-area and low-cost electronic devices are primarily based on amorphous silicon (a-Si) or polycrystalline silicon (poly-Si) transistors on glass, and the device performance is limited due to low carrier mobilities in amorphous silicon (a-Si) or poly-Si. These transistors are being used in various applications, such as flat panel displays (FPDs), solar cells, image sensor arrays and digital X-ray imagers.

There has been growing interest in the use of plastic as a substrate for large-area electronics due to various beneficial attributes of plastic, such as availability, low cost, light weight and flexibility. However, the fabrication of transistors such as field effect transistors (FETs) or thin film transistors (TFTs) is difficult on plastic substrates because the processing temperatures of the transistors should be maintained below the transition temperature of the plastic.

Single crystalline Si is traditionally used in microelectronic circuits with high mobility ˜1000 cm²/V·s for electrons and ˜400 cm²/V·s for holes. However, there exists no practical way to grow high quality single crystal Si at low temperature directly on flexible substrates. Although, deposition of a-Si at low temperature on flexible substrate is possible, a-Si is not capable of high-speed operation because of the low electron mobility (<1 cm²/V·s) caused by high defect densities.

Some fabrication methods counter this shortcoming of plastic substrates by employing assembling techniques. It includes fabricating circuits and devices on a first substrate, referred to as “mother” substrate and then separating and transferring the device to another substrate. “Separation and transfer fabrication” approaches all have the common feature of separating finished circuits from the mother substrate after all fabrication steps are completed. Some of these approaches remove all materials, processing, and processing temperature constraints. However, these approaches are still far from mature with limited final substrate sizes.

Accordingly, it is desirable to have a fabrication method, which enables low cost and more efficient methods for large-area devices. Also, it is desirable to provide large-area flexible electronics that is more efficient and provides improved device properties in terms of reliability.

### BRIEF DESCRIPTION

In accordance with one aspect of the present technique, a nanowire structure is provided. The nanowire structure includes a nanowire defining an axis, where the nanowire includes a first end and a second end, and where the first end is axially spaced from the second end. Further, the nanowire structure includes magnetic segments that are coupled to the first and second ends of the nanowire.

In accordance with another aspect of the present technique, a device is provided. The device includes a substrate having a nanowire structure disposed thereon. The nanowire structure includes a nanowire and magnetic segments. The device also includes a first magnetic microelectrode and a second magnetic microelectrode coupled to the magnetic segments of the nanowire structure. The nanowire structure is configured to electrically couple the first and second magnetic microelectrodes. The nanowire structure is configured to be aligned in a predetermined direction under the influence of a magnetic filed.

In accordance with yet another aspect of the present technique, an article is provided. The article includes a nanoscale semiconducting pathway having a first end and a second end. Further, the article includes magnetically responsive portions coupled to the first and second ends of the pathway. The magnetically responsive portions are configured to align the article in response to a magnetic field.

In accordance with another aspect of the present technique, a method of making a nanowire structure is provided. The method includes providing a substrate, forming a porous layer on the substrate, depositing a magnetic material layer in the pores to form first magnetic segments. Further, the method includes depositing a nanowire material on the magnetic material layer to form nanowires on each of the first magnetic segments. Furthermore, a second magnetic material layer is deposited on the nanowires.

In accordance with yet another aspect of the present technique, a method of making a device is provided. The method includes providing a substrate, disposing a first magnetic microelectrode and a second magnetic microelectrode on the substrate, and disposing a plurality of nanowire structures between the first and second contact pads. Further, the method includes aligning the plurality of nanowire structures, such that nanowire structures are parallel to each other and are in operative association with the first and second electrodes to electrically couple the first and second electrodes.

### DRAWINGS

These and other features, aspects, and advantages of the present invention will become better understood when the following detailed description is read with reference to the accompanying drawings in which like characters represent like parts throughout the drawings, wherein:

FIG. 1 is a cross-sectional side view of an exemplary nanowire structure employing a shell according to certain embodiments of the present technique;

FIG. 2 is a cross-sectional side view of another exemplary nanowire structure employing a shell according to certain embodiments of the present technique;

FIG. 3 is a cross-sectional side view of an exemplary nanowire structure employing a nanowire having a p-n diode according to certain embodiments of the present technique;

FIG. 4 is a cross-sectional side view of an exemplary nanowire structure employing a nanowire having a p-i-n junction transistor according to certain embodiments of the present technique;

FIG. 5 is a cross-sectional side view of an exemplary device employing a nanowire structure according to certain embodiments of the present technique;

FIG. 6 is a top view of the embodiment illustrated in FIG. 5;

FIG. 7 is a cross-sectional side view of another exemplary device employing a nanowire structure according to certain embodiments of the present technique;

FIG. 8 is a top view of the embodiment illustrated in FIG. 7;

FIGS. 9-11 are schematic illustrations of various steps involved in the method of making the nanowire structures according to certain embodiments of the present technique; and

FIG. 12 is a schematic illustration of various steps involved in the method of making of a device employing the nanowire structures according to certain embodiments of the present technique.

### DETAILED DESCRIPTION

Nanowires made of materials, such as semiconductors or inorganic materials, are being used in large area electronic devices to improve the performance of the devices. Also, the nanowires are being used in conventional electronic devices to achieve improved device behavior, while allowing for inexpensive and fast manufacturing processes. The semiconductor nanowires are single-crystal and have comparable or better electron or hole mobility than their corresponding bulk forms. These nanowires are mostly employed in the form of films of semiconductor materials, which may be used in electronic devices to make high performance, low cost devices on large and flexible substrates. In order to effectively employ such nanowires in electronics devices, it is desirable to form low-resistance and reliable electrical contacts to these nanowire in a manufacturable fashion. As used herein, “manufacturable” implies that the electrical contacts may be made at a high rate in a scaleable process (across large substrates), with precise control of the contact area, contact resistance, and yield. However, while employing electrical contacts in large-area electronics devices, a high level of control over the position of the nanowire structures on a substrate or within layers is desirable. For example, in integrated electronics and photonics nanotechnologies, it may be desirable to align these nanowires relative to the components of the devices.

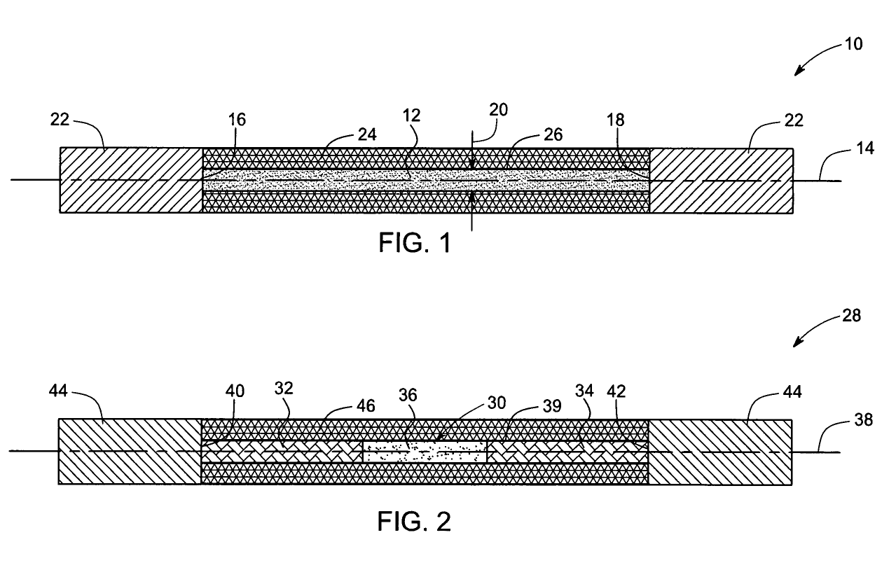

FIG. 1 illustrates a nanowire structure 10 having a nanowire 12 defining a nanoscale semiconducting pathway along an axis 14. In the illustrated embodiment, the nanowire 12 has first and second ends 16 and 18, wherein the first end 16 is axially spaced from the other end 18. As used herein, the term “nanowire” refers to any elongated conductive or semiconductive structure that includes one or more cross sectional dimension that is less than 1000 nanometers, or preferably 100 nanometers. In some embodiments, the nanowire 12 may be a single crystal nanowire. As used herein, the term “nanowire” may also refer to other elongated nano-structures, such as nanorods, nanotubes, nanoribbons, and the like. In some embodiments, the nanowires may also include one or more nanorods. In these embodiments, the nanorods may be connected in series such that they form a path by which electrons can travel between the first and second ends 16 and 18 of the structure 10. As used herein, the term “nanorod” refers to an elongated conductive or semiconductive structure similar to a nanowire but having an aspect ratio (length:width) less than that of a nanowire. In some embodiments, two or more nanorods may be coupled along their longitudinal axis to form a nanowire.

In certain embodiments, the diameter 20 of the nanowire 12 may be in a range from about 5 nanometers to about 1000 nanometers, and preferably from about 10 nanometers to about 300 nanometers. The length of the nanowires may be in a range from about 1 micron to few centimeters, and preferably from about 1 micron to about 100 microns for the devices disclosed herein. In certain embodiments, the nanowire 12 may include semiconductor materials, for example, silicon. In certain embodiments, the nanowire 12 may include germanium, III-V semiconductors, II-VI semiconductors, IV-IV semiconductors, or combinations thereof

As will be described in detail below with regard to FIGS. 2-4, in certain embodiments, a portion of a nanowire, such as the nanowire 12, may be doped. In some embodiments, doping may enhance conductivity in the doped portion of the nanowires, thereby enhancing electronic properties of the nanowire for use in an electronic device. In these embodiments, the nanowire 12 may be doped prior to inclusion in the device. Further, the nanowire 12 may be doped differently at different portions along the axis 14. In these embodiments, the p-type dopant may include boron, aluminum, indium, magnesium, zinc, cadmium, mercury, carbon, silicon, or combinations thereof. Similarly, in these embodiments, the n-type dopant may include silicon, germanium, sulfur, selenium, tellurium, , or combinations thereof.

Referring again to FIG. 1, in certain embodiments, the structure 10 may also include magnetic segments 22 disposed on the first and second ends 16 and 18 of the nanowire 12. In these embodiments, the segments 22 may be in operative association with the nanowire 12 to conduct electrons or holes between the first end 16 of nanowire 12 and the second end 18 of the nanowire 12. In certain embodiments, the magnetic segments 22 may form Ohmic contacts with the first and/or second ends 16 and/or 18 of the nanowire 12. As will be described in detail below, the magnetic segments 22 may be magnetically responsive portions of the nanowire 12, which may be configured to align the structure 10 in a predetermined direction under the influence of a magnetic field. In certain embodiments, the segments 22 may be used to align the structure 10 between a pair of magnetized electrodes or contact pads on a substrate. In these embodiments, either local magnetic fields by magnetized microelectrodes or an external magnetic field may be used to align the structure 10. In some embodiments, the external magnetic field may be applied in addition to the local magnetic field of magnetized microelectrodes.

In certain embodiments, the magnetic segments 22 may include magnetic metals, such as nickel, cobalt, iron, or combinations thereof In other embodiments, the magnetic segments 22 may include a ceramic, a polymer, or other materials which are magnetically responsive.

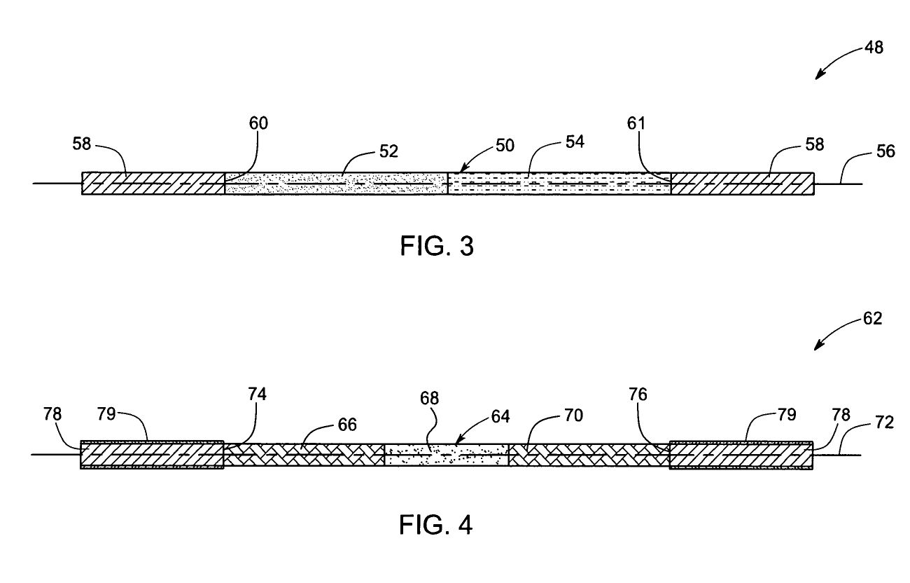

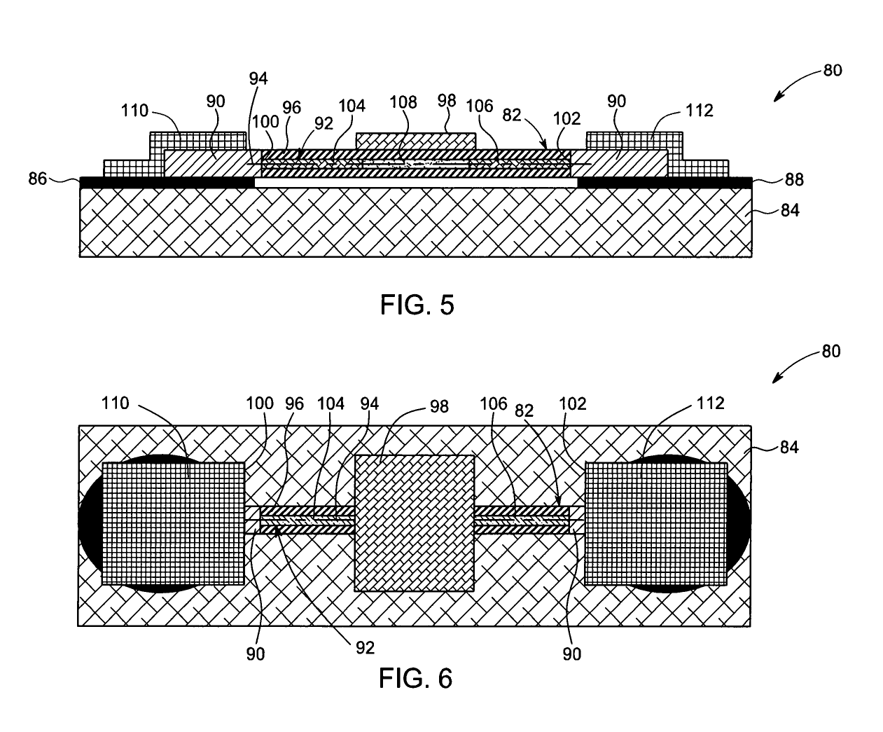

Further, in certain embodiments, the structure 10 may include a shell 24 coupled to the nanowire 12 and surrounding at least a portion of the nanowire 12. In these embodiments, the shell 24 may be spaced radially from the axis 14 of the nanowire 12. In the illustrated embodiment, the shell 24 surrounds the portion of the nanowire 12 located between the first and second ends 16 and 18. The shell 24 may have a thickness in a range from about 5 nanometers to about 1000 nanometers, and preferably from about 20 nanometers to about 200 nanometers. Such a structure 10 may be employed in transistors. When employed in a transistor, a single crystal nanowire results in high carrier mobility, thereby resulting in high performance. As will be described in detail below with regard to FIGS. 5-8, in embodiments where the structure 10 is employed in a transistor device, the interface 26 formed between the nanowire 12 and the shell 24 may facilitate high channel mobility. In some of these embodiments, the interface may be a semiconductor-oxide interface, with the nanowire 12 being the semiconductor material and the shell 24 being the oxide material. In these embodiments, the oxide of the shell 24 may be a native oxide of the semiconductor material 12. That is, in these embodiments, the oxide of the shell 24 may be grown on the semiconductor material of the nanowire 12 by oxidizing or anodizing the material of the nanowire 12. For example, the nanowire 12 may include silicon and the shell 24 may include native silicon oxide of the silicon of the nanowire 12. Alternatively, the nanowire structure, such as structures 48 and 62 of FIGS. 3 and 4, which do not employ the shell may be employed in light emitting diodes (LEDs), or photodetectors to obtain high efficiency due to single crystal nanowires.

In certain embodiments, the shell 24 may be an insulator, such as silicon dioxide, such that the electrons traveling through the nanowire 12 between the first and second ends 16 and 18 of the structure 10 may not migrate to the semiconductor shell 24. In these embodiments, the shell 24 may separate impurities from the nanowire 12, thereby reducing impurity related scattering from the surface of the nanowire 12 at the interface 26. This reduced scattering in turn may result in enhanced channel mobility of the nanowire 12. In an exemplary embodiment, the channel mobility at the interface 26 may be about 1000 cm²/volt-second for silicon. Also, in some embodiments, the material compatibility at the interface 26 of the nanowire 12 and the shell 24 may be enhanced. For example, by growing the native oxide, material properties, such as lattice constant may be matched at the interface 26, thereby reducing stress related defects in the device.

Although not illustrated, in certain embodiments, the structure 10 may further include a dielectric material layer disposed on the nanowire 12. In other embodiments, the dielectric material layer may be disposed on the shell 24, thereby making a three layered structure. In exemplary embodiments, the dielectric material layer may include materials, such as but not limited to, silicon oxide, or silicon nitride.

FIG. 2 illustrates an alternate embodiment of the structure 10 shown in FIG. 1. In the illustrated embodiment, the structure 28 includes a nanowire 30. In the illustrated embodiment, the nanowire 30 includes doped portions 32 and 34 disposed on either side of the undoped portion or the lowly doped portion 36. As illustrated, the portions 32, 34 and 36 of the nanowire 30 are axially distributed along the axis 38 and are bound by the first and second ends 40 and 42 of the nanowire 30. In some embodiments, the doped portions 32 and 34 may be similarly doped. That is, both the doped portions 32 and 34 may be either p-type doped or n-type doped. Also, the portion 36 may be intrinsic or have relatively less doping concentration. In the illustrated embodiment, the portions 32 and 34 are heavily doped and include the same doping type, whereas, the portion 36 may be either intrinsic or may be relatively lightly doped relative to portions 32 and 34. For example, the portions 32 and 34 may include p+-doped and the portion 36 may be intrinsic or lowly p-doped. As will be appreciated, the illustrating doping profiles are exemplary profiles and the structures, such as the structure 28, may include several other doping profiles.

Further, the structure 28 includes a shell 46 disposed on the nanowire 30 and forming the interface 39 with the nanowire 30. The structure 28 further includes magnetic segments 44 disposed on the first and second ends 40 and 42 of the structure 28.

In embodiments where such a structure 28 is employed in a transistor as a channel, an electrode, such as a gate electrode may be disposed on only the portion 36 as opposed to completely covering the nanowire 28 when it is un-doped. In these embodiments, the gate electrode may also partially overlap with the portions 32 and 34. In these embodiments, the portion 36 may act as the active region of the channel of the transistor.

As noted above, in embodiments where nanowires, such as nanowires 12 and 28 are employed in large area electronics devices having flexible or rigid substrates, the magnetic segments may facilitate alignment of the nanowires with respect to the components of the devices by using magnetic fields. As will be appreciated, the magnetic shape anisotropy and high remnant magnetization of the magnetic segments 22 or 44 facilitates the orientation of nanowires in small external magnetic fields with high control to achieve desirable orientation of the nanowire structures 10 or 28. Furthermore, local magnetic fields generated by local magnetized electrodes, such as magnetic microelectrodes may be used to facilitate the distribution of nanowires on a substrate, such as a substrate for the large-area electronics devices. In an exemplary embodiment, a single nanowire, such as a nanowire 12 or 28 having magnetic segments 22 or 44 may be aligned between lithographically patterned magnetic microelectrodes. In this embodiment, a substrate having lithographically defined magnetic features is placed on the bottom of a chamber. Nanowires with magnetic segments in suspension are then introduced into the chamber in the presence of an aligning external magnetic field. Subsequently, as the nanowires settle towards the surface of the substrate, they reach the proximity of the local magnetic fields produced by the lithographic features, and are drawn into regions of strong local field gradients, such as the gap between two closely-spaced lithographic features. It should be noted that, if the gap is smaller than the size of the nanowires, and the nanowire concentration in the suspension is low, then single nanowires may bridge the gap between the lithographic features and become trapped between the features, such as the microelectrodes.

In some embodiment, the nanowires may be suspended in low viscosity liquids, such as water or ethanol, to be dispersed on a substrate. In these embodiments, the segmented nanowires precipitate from the solutions over the course time. Simultaneously, aggregation may also occur due to inter-wire magnetic forces. Suspending the nanowires in relatively more viscous media may reduce aggregation and precipitation of the nanowires in the liquid, thereby facilitating uniform dispersion of nanowires in the liquid. However, relatively lower viscosity liquids may be employed to limit inter-nanowire interactions in the diluted suspension. Further, the diluted suspension may also reduce the occurrence of multiple wires trapping between a pair of components, such as electrodes of the electronics device. Further, the trapping of the nanowires may be enhanced by the application of a uniform magnetic field parallel to the long axis of the magnetic components, which pre-orients the suspended nanowires. This further reduces aggregation of wires in the suspension, and large numbers of single wires reach the bottom of the cell. Additionally, by aligning the dipole moments of the wires with the poles of the magnetic microelectrodes, the configuration for trapping in the gaps is optimized. In some embodiments, the nanowires may be re-suspended in the liquid by ultrasonic agitation.

FIGS. 3 and 4 illustrate alternate embodiments of doping profiles of nanowires in accordance with embodiments of the present techniques and depicted generally as structures 48 and 62, respectively. In the illustrated embodiment of FIG. 3, the structure 48 includes a nanowire 50 having a p-n junction diode. In embodiments where the nanowire 50 employs a semiconductor material, the structure 48 may be used for light emitting diodes (LEDs) or photodetectors. For example, in embodiments where the nanowire 50 employs one or more direct bandgap materials, the structure 48 may be used for LEDs. The nanowire 50 includes doped portions 52 and 54 disposed adjacent each other along the axis 56. One of the portions 52 or 54 may be p-doped and the other one of the portions 52 or 54 may be n-doped. The structure 48 further includes magnetic segments 58 disposed on first and second ends 60 and 61 of the nanowire 50.

In the illustrated embodiment of FIG. 4, the structure 62 includes a p-i-n junction diode. In the illustrated embodiment, the structure 62 includes nanowire 64 having three separate doped regions 66, 68 and 70. The region 66 may be n+-doped, the region 70 may be p+-doped, and the region 68 may be intrinsic or lowly doped to form an n-i-p diode. Alternatively, the region 66 may be p+-doped, the region 70 may be n+-doped, and the region 68 may be intrinsic or lowly doped to form a p-i-n diode. As illustrated, the three regions are spaced along the axis 72 of the nanowire 64 and are bound within first and second ends 74 and 76 of the nanowire 64. The structure 62 further includes magnetic segments 78 disposed on either side of the nanowire 64.

Further, in certain embodiments, the nanowire structure 62, such as structure 62 may include a capping layer, such as a capping layer 79, which may be disposed radially around the magnetic segments 78. The capping layer 79 may facilitate the reduction in agglomeration of the nanowire structures in a solution. In these embodiments, the capping layer 79 may be disposed such that it covers the portion of the magnetic segments 78, which is parallel to the longitudinal axis of the nanowire 64, and does not cover the ends of the magnetic segments 78. In some embodiments, the thickness of such a capping layer 79 may vary in a range from about 0.1 microns to about 100 microns, and preferably from about 10 microns to about 50 microns.

FIGS. 5 and 6 illustrate a device 80 employing a nanowire structure 82. In the illustrated embodiment, the device 80 includes a transistor. In the illustrated embodiment, a substrate 84 includes source and drain contact pads or magnetic microelectrodes 86 and 88. In certain embodiments, the substrate 84 may include plastic, silicon, glass, or quartz. Non-limiting examples of a rigid plastic substrate may include polycarbonate, or polystyrene. Alternatively, non-limiting examples of a flexible plastic substrate may include polyolefin, polyamide. Additionally, in certain embodiments, the substrate 84 may include other circuit or structural elements that are part of the ultimately desired device. In these embodiments, the substrate 84 may include electrical circuit elements, such as electrical segments, other conductive paths, such as wires, vias, optical or opto-electrical elements, such as lasers, light emitting diodes (LEDs), or structural elements, such as micro-cantilevers, pits, wells, posts, etc.

FIG. 6 illustrates top view of the device 80 of FIG. 5. Although in the illustrated embodiment of FIG. 6, the source and drain contact pads 86 and 88 are shown as having ellipse shapes, as will be appreciated, the contact pads 86 and 88 may have various other shapes as well. The shape of the source and drain contact pads 86 and 88 may be used to control the local magnetic field and the number of nanowires structures 82 that may be aligned between the source and drain electrodes. In these embodiments, the structures 82 may act as a channel region for the transistor. In these embodiments, the charge carriers, i.e., electrons and/or holes may transport through the structures 82, which generally include single crystal nanowires 92, thereby resulting in high mobility, which is otherwise difficult to achieve with amorphous and poly-silicon channel regions.

As used herein, the term “aligned” indicates that the majority of the longitudinal axis of the majority of the structures 82 is aligned within 30 degrees of a predetermined direction. Although in certain embodiments, the structures 82 may be aligned within 60 percent to 90 percent of the predetermined direction. For example, in the illustrated embodiment, the predetermined direction is the direction along the line joining the center of the source contact pad 86 to the center of the drain contact pad 88 and a majority of the nanowire structures are within 90 percent of the predetermined direction. As noted above, the segments 90 may be used to align the structures 82 in a predetermined direction. In certain embodiments, the structures 82 may be aligned under the influence of the magnetic field of the contact pads 86 and 88. In these embodiments, the magnetic segments 90 realign themselves under the influence of the magnetic field of the magnetic microelectrodes, such as contact pads 86 and 88, thereby aligning the nanowire structures 82 between the contact pads 86 and 88. In alternate embodiments, an external magnetic field may be applied to the structures 82 to align the structures 82 in a predetermined direction. In these embodiments, the external magnetic field may either be applied in combination with the magnetic field of the magnetic microelectrodes, or separately to align the structures 82. In an exemplary embodiment, the strength of the external magnetic field may be in a range from about 5 Gauss to about 50 Gauss.

Although in the illustrated embodiment the source and drain contact pads 86 and 88 are coupled using a single nanowire structure, however, it should be noted that a plurality of such structures may be employed to couple the source and drain contact pads 86 and 88 by controlling the shape of magnetized microelectrodes. Also, when a plurality of such structures 82 are employed between the source and drain contact pads 86 and 88, the structures may be aligned such that their respective axis 94 are parallel to each other to provide high current handling capacity along the direction parallel to the axis 94.

In certain embodiments, the contact pads 86 and 88 may include magnetic material. In these embodiments, the material of the contact pads and the magnetic segments 90 of the structure 82 may be the same. As will be described in detail below, in an exemplary embodiment, the contact pads 86 and 88 may have an elliptical shape to facilitate orientation of nanowire structures, such as structures 82.

The nanowire structure 82 may include a nanowire 92, and may be disposed between and electrically coupled to the contact pads 86 and 88 along the axis 94. The structure 82 further includes shell 96 surrounding the nanowire 92. In the illustrated embodiment, a gate contact pad 98 is coupled to a portion of the structure 82. Depending on the doping profile of the nanowire 92, the gate contact pad 98 may either cover the entire portion of the nanowire 92 disposed between the first and second ends 100 and 102, or may be disposed only on a portion of the nanowire 92. In the illustrated embodiment, the nanowire 92 may include similarly highly doped regions 104 and 106 disposed on either side of a relatively lightly doped region 108. In this embodiment, the region 108 acts as the active region of the channel or the nanowire 92. Therefore, when employing the gate electrode, the gate electrode may be disposed such that it covers mainly the region 108, and may overlap partially with the adjacent regions 104 and/or 106. As illustrated, the gate contact pad 98 stretches over the entire length of the region 108 and partially overlaps the regions 104 and 106. Hence, relatively smaller amount of the gate contact pad material may be employed in the transistor as opposed to the transistor employing an undoped nanowire structure, such as the structure 10 (see FIG. 1). In certain embodiments, the gate contact pad 98 may be used to modulate the electron flow in the nanowire 96. In certain embodiments, the gate contact pad 98 may include an electrically conductive material, such as a metal. In some embodiments, the nanowire 92, the shell 96 and the gate contact pad 98 may form a metal-oxide-semiconductor interface. In these embodiments, the nanowire 92 may include a semiconductor, such as silicon, the shell 96 may include a native oxide of the semiconductor material of the nanowire 92, and the gate contact pad 98 may include a metal. In these embodiments, the transistor may be a metal-oxide-semiconductor field effect transistor (MOSFET).

As will be appreciated, the position of the source and drain contact pads 86 and 88 may be interchanged without affecting the performance of the device 80. In certain embodiments, the source and drain contact pads 86 and 88 may be coupled to capping pads, such as metal caps 110 and 112, respectively. In certain embodiments, the caps 110 and 112 may be used to secure the nanowire structure 82 to the source and drain contact pads 86 and 88 once they are aligned in the predetermined direction between the source and drain contact pads 86 and 88.

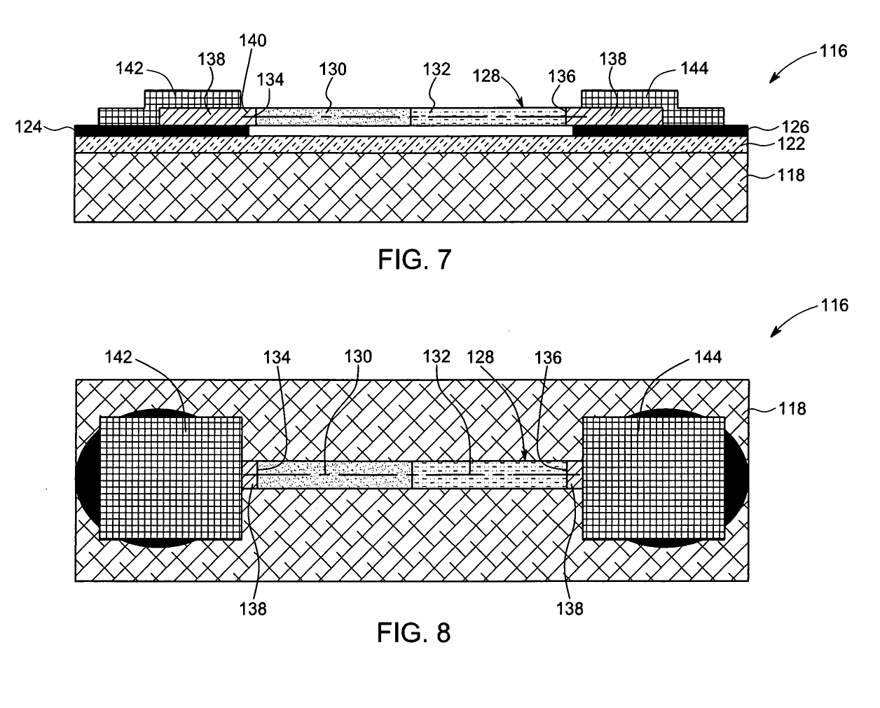

FIGS. 7-8 illustrate alternate embodiments of the device 80 of FIGS. 5 and 6. In the illustrated embodiment, the device 116 includes a substrate 118. The substrate 118 may be a flexible or rigid substrate. In the illustrated embodiment, if the substrate 118 is not electrically insulating, an insulating layer, such as a dielectric layer 122 is disposed on the substrate 118. The device 116 further includes first and second magnetic microelectrodes 124 and 126 disposed on the dielectric layer 122. Further, a nanowire structure 128 is disposed on and coupled to the first and second magnetic microelectrodes 124 and 126. As with the structure 82 of FIGS. 5 and 6, the structure 128 may be aligned in a predetermined direction. The structure 128 may include a nanowire 130 having a first end 132 and a second end 134. The structure 128 further includes magnetic segments 136 coupled to the first and second ends 132 and 134 of the nanowire 130. Further, metal caps 142 and 144 may be disposed on the segments 136 to secure the structure 128 to the first and second magnetic microelectrodes 124 and 126. As with the illustrated embodiment of FIGS. 5 and 6, depending upon the current levels and charge mobility, several of such structures 128 may be employed between the first and second magnetic microelectrodes 124 and 126.

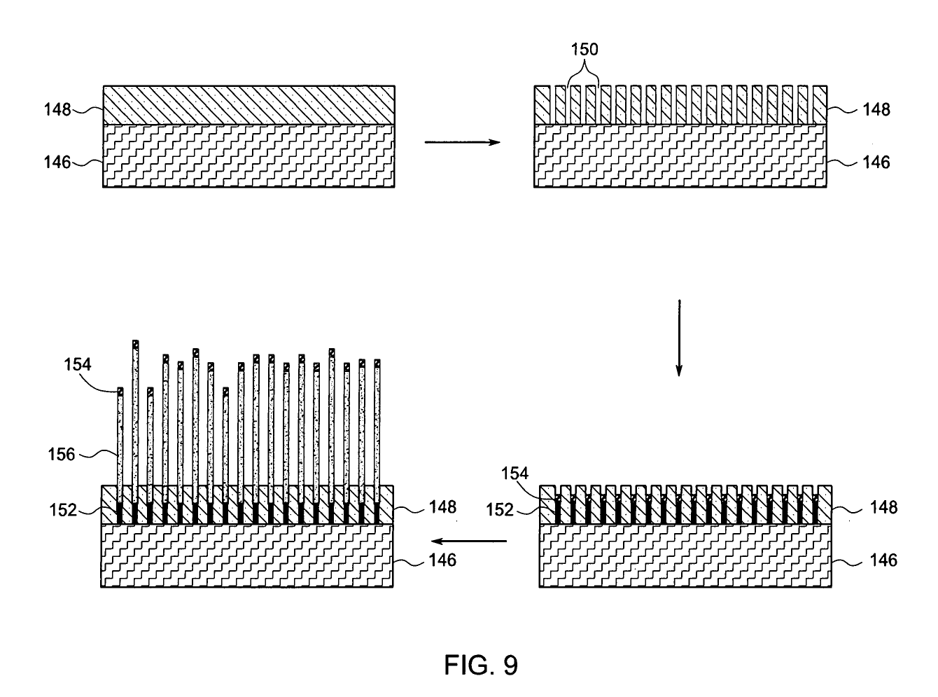

FIGS. 9-11 illustrate various steps involved in the method of making the nanowire structures, such as structures 10, 28, 48 or 62. FIG. 9 illustrates the steps of growing a nanowire having magnetic segments coupled thereto on a substrate. In the illustrated embodiment, a substrate 146, such as a semiconductor or glass substrate is provided. In an exemplary embodiment, the semiconductor substrate may include materials, such as but not limited to, silicon, gallium arsenide, aluminum gallium arsenide, or combinations thereof Next, a metal film 148, comprising aluminum, is deposited on the substrate 146. In certain embodiments, the metal film 148 is configured to develop pores 150 upon anodization or oxidation. In one embodiment, anodization of the metal film 148 may be performed by employing processes, such as wet chemical processes. In an exemplary embodiment, the metal may include aluminum, which upon oxidation may convert into porous alumina with uniform vertical channels. In some embodiments, the pore density of the anodized alumina may be in a range from about 10⁷ pores/cm² to about 10¹¹ pores/cm². Alternatively, a porous template layer, such as anodic aluminum oxide layer, may be attached directly onto the substrate 146. Although not illustrated, an additional dissolvable metal layer may be deposited between the metal film 148 and the substrate 146. In certain embodiments, this dissolvable metal layer may be dissolved in certain solutions, thereby detaching the metal film 148 from the substrate 146, as described below. In some embodiments, the metal layer may include metals, such as but not limited to, titanium, chromium, tungsten, titanium-tungsten, copper, gold, or combinations thereof.

Subsequently, magnetic material layer 152 is deposited into the pores 150 to form first magnetic segments. In certain embodiments, this magnetic material layer 152 may be employed to form the magnetic segments of the nanowire structures. In these embodiments, the layer 152 may include the material, which is desirable as the magnetic segments. For example, the magnetic material layer 152 may include nickel, cobalt, or iron, or combinations thereof In an exemplary embodiment, electro-chemical deposition may be employed to deposit magnetic material layer 152 into the pores 150. The fill factor of layer the 152 may be reduced to increase the space between individual nanowires. In an exemplary embodiment, the fill factor of the layer 152 is reduced by using an easily oxidizing metal layer, such as titanium. Further, a catalyst 154, such as gold may be deposited on the magnetic material layer 152. In certain embodiments, the magnetic catalyst 154 may be deposited by employing processes, such as electrochemical deposition, e-beam evaporation, thermal evaporation, or sputtering. In an exemplary embodiment, the catalyst 154 may be deposited using electro-chemical deposition. In certain embodiments, the catalyst 154 may be used to facilitate the growth of the nanowire structure.

Next, a layer 156 of the nanowire material is deposited on the magnetic material layer 152 to form nanowire of the nanowire structure. In certain embodiments, the layer 156 of the nanowire material may include silicon, germanium, group III-V semiconductors, group II-VI semiconductors, group IV-IV semiconductors, or combinations thereof. In some embodiments, the layer 156 of the nanowire material may be deposited using chemical vapor deposition, such as one using vapor-liquid-solid mechanism. In these embodiments, the substrate 146 having the magnetic material layer 152 in the pores 150 and/or the catalyst 154 may be transferred to a chemical vapor deposition chamber prior to depositing the layer 156 of the nanowire material. Further, if a catalyst 154, such as gold, is employed, the catalyst is heated to form a liquid droplet and absorb the material of the nanowire and deposit it on the magnetic material layer 152 underneath. In the embodiments where a portion of the nanowire is doped, the dopants may be introduced as gas species in the chemical vapor deposition chamber during the deposition of the layer 156.

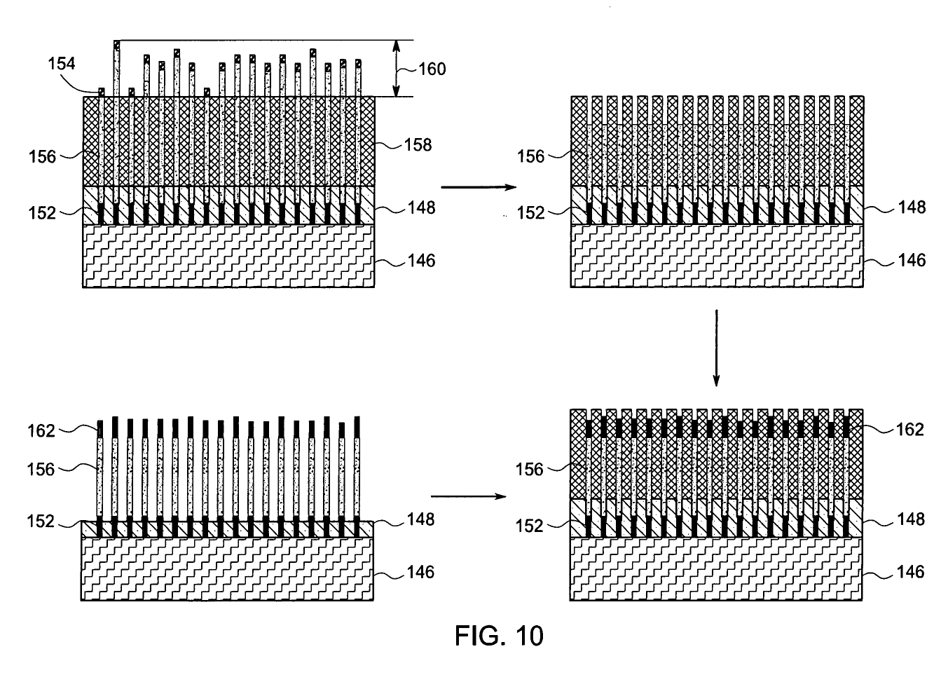

FIG. 10 illustrates steps of depositing second magnetic segment 162 on the layer 156 to form a nanowire having magnetic segments on either side. As illustrated in FIG. 9, the layer 156 of the nanowire material grown on the substrate 146 may be of non-uniform lengths, which may be undesirable for use in electronic devices. Before depositing the second magnetic segment 162, in certain embodiments, the length of the layer 156 of the nanowire material may be made uniform by etching away portions 160 of the layer 156, as described below. In the illustrated embodiment, a photoresist or other polymer filling material 158 may be coated on the layer 156. In an exemplary embodiment, the photoresist layer 158 may be spin coated on the layer 156 at a low temperature in a range from about 100° C. to about 150° C. The surface of the photoresist 158 so formed may be flat. In these embodiments, oxygen plasma may be employed to etch the photoresist to expose the nanowires 160, i.e., from the layer 156. Wet etch may be employed to etch away the extended portions 160 of the layer 156, thereby forming the nanowires having uniform lengths.

Subsequently, the second metal segment layer 162 is deposited on the layer 156 of the nanowire material to form the second magnetic segments 162 using the pores of the photoresist 158 as a template. In an exemplary embodiment, the magnetic segments 162 may be deposited by employing processes, such as electro- chemical deposition. Subsequently, the photoresist 158 is removed by dissolving it in a suitable solvent, such as acetone, PRS1000, PRS3000 or other resist strippers, or etching by oxygen plasma. Optionally, a portion of the metal film 148 of anodized alumina may also be etched away by controlled wet etching, such as buffered oxide etch, or KOH or NaOH, to fully expose the semiconductor segment.

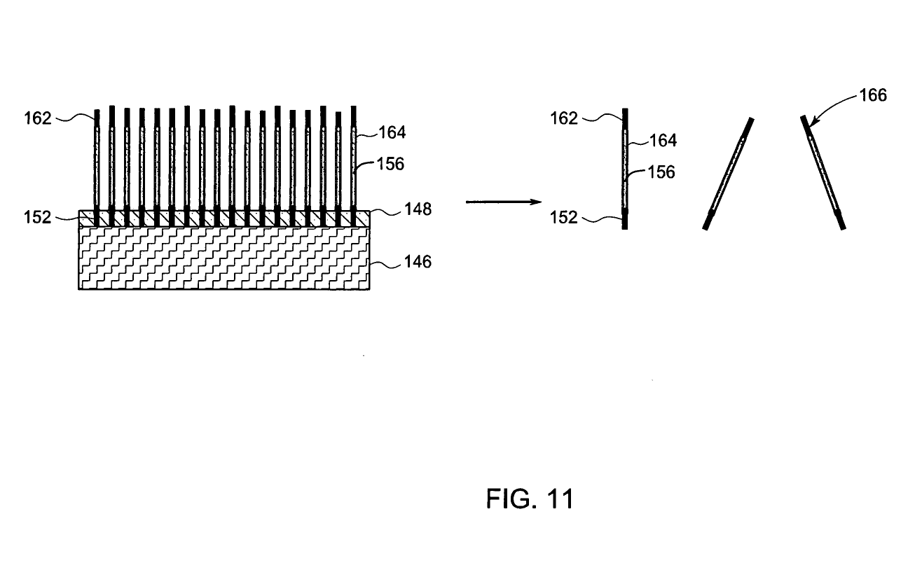

As noted above, for applications such as LEDs and photodetectors, the steps illustrated in FIG. 11 may not be desired. In such applications, after the steps illustrated in FIG. 10, the photoresist may be washed away by using the techniques mentioned above to obtain nanowires without the shell. Subsequently, these nanowires may be subjected to doping to form desirable doping profiles, such as the doping profiles illustrated in FIGS. 3, 4, 7 and 8. FIG. 11 illustrates the optional step of forming a shell on the nanowire of FIGS. 9 and 10. Subsequent to depositing the magnetic segments 162 and removing the photoresist 158, the layer 156 of the nanowire material is oxidized in a controllable fashion to grow native oxide layer 164 on the layer 156 of the nanowire material. In an exemplary embodiment, where the layer 156 of the nanowire material includes silicon, the native oxide layer of silicon oxide is formed upon oxidation of the layer 156 of the nanowire material. In the illustrated embodiment, subsequent to forming the native oxide layer 164, the anodized aluminum oxide (AAO) template layer 148 is dissolved, thereby providing separated individual nanowire structures 166, similar to the structures 10, 28, 48 or 62. In certain embodiments, the step of dissolving the template layer 148 may include controllable wet etch in KOH or NaOH solution. The released nanowires are washed in water and/or solvents several times to remove the residual contaminants from the structures, with a permanent magnet placed outside the container. In the embodiments where an additional metal layer is deposited between the substrate 146 and the metal film 148, the metal layer may be dissolved by using wet etch, to provide separated nanowire structures 166.

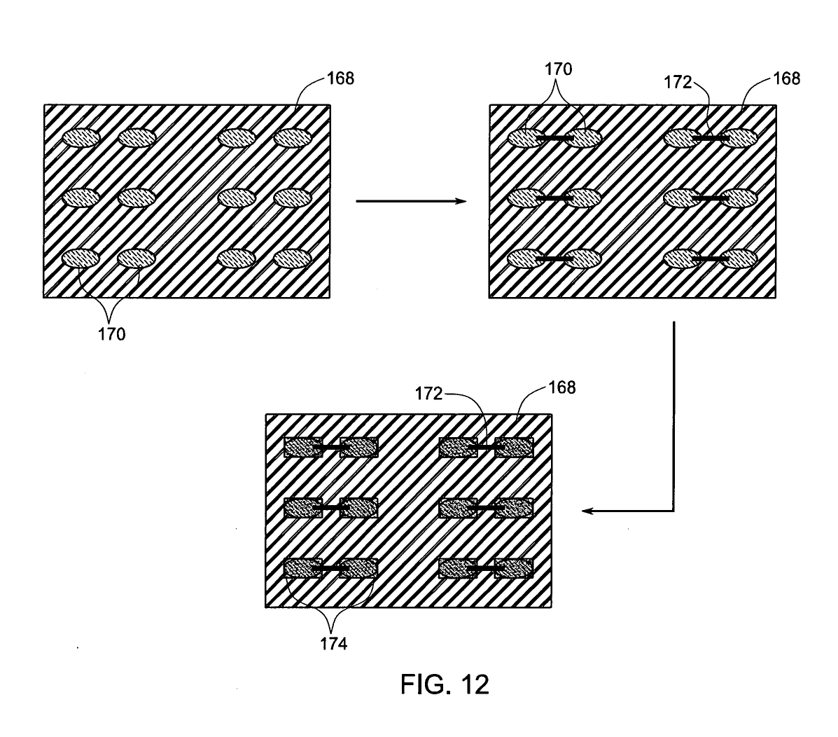

FIG. 12 illustrates an exemplary method of forming a device; such as the devices 80 and 116 illustrated in FIGS. 5-8, employing the nanowire structures, such as structures 10, 28, 48 or 62. In certain embodiments, the device may include large area electronics devices on a flexible substrate. In the illustrated embodiment of FIG. 12, a substrate 168, such as a flexible plastic substrate is provided. Subsequently, metal contact pads or microelectrodes 170 are deposited on the substrate 168. The magnetic microelectrodes 170 may be similar to the source and drain contact pads of FIGS. 5-6 or first and second magnetic microelectrodes of FIGS. 7-8. In certain embodiments, the magnetic microelectrodes 170 may be of shapes, such as rectangular, elliptical, or circular. For example, the magnetic microelectrodes 170 may be made in an elliptical shape to control the local magnetic field distribution. In this exemplary embodiment, the separation of the magnetic microelectrodes 170 may be based on the length of the nanowires 172. For example, in one embodiment, the lengths of the nanowires 172 may be shorter than the gap between the magnetic microelectrodes 170 may be bridged by a single nanowire.

As noted above, in certain embodiments a local magnetic field may be applied between these magnetic microelectrodes to align the nanowire structures. In some embodiments, prior to disposing the nanowires 172 between the magnetic microelectrodes 170, the magnetic microelectrodes 170 may be magnetized in a magnetic field or for example, 5 kilo Gauss. In the embodiments where the magnetic microelectrodes 170 are elliptical, the magnetic filed between a pair of these magnetic microelectrodes may be maximum along the line parallel to the major axis of the two ellipses and joining the center of the ellipses. Therefore, in embodiments where a single nanowire structure is desirable between each pair of the magnetic microelectrodes 170, it may be desirable to have the magnetic microelectrodes 170 in the shape of an ellipse. Similarly, in embodiments where it is desirable to have a plurality of nanowire structures between each pair of the magnetic microelectrodes 170, it may be desirable to have the magnetic microelectrodes 170 in a shape, which has a relatively uniform magnetic field along its faces. For example, it may be desirable to have rectangular magnetic microelectrodes 170.

In some embodiments, subsequent to forming the magnetic microelectrodes 170, a photoresist window (not shown) may be formed between the magnetic microelectrodes 170 for selective disposal of nanowire structures. Subsequently, nanowire structures 172 may be disposed between the magnetic microelectrodes 170. In certain embodiments, the step of disposing the nanowire structures 172 may include dispersing these structures 172 in a fluid and disposing the solution having the solvent and the structures 172 suspended in the fluid between the magnetic microelectrodes 170. In some embodiments, the fluid used to disperse the structures 172 may include water, methanol, ethanol, iso-propanol, or combinations thereof. As with the nanowire structures 10, 28, 48 or 62, the nanowire structures 172 may include a nanowire, optionally a shell surrounding the nanowire, and magnetic segments disposed on either side of the nanowire. Subsequent to disposing the structures 172 between each of the pairs of the magnetic microelectrodes 170, the structures 172 are aligned in a predetermined direction. In certain embodiments, the alignment of the structures 172 may be facilitated by interaction between the magnetic segments of the structures 172 and the magnetic microelectrodes 170, and/or by application of an externally applied magnetic field. In the illustrated embodiment, subsequent to aligning the nanowires 172 between the magnetic microelectrodes 170, the end of the nanowires 172 may be capped by employing metal pads 174, such as source and drain caps. Optionally, in case of a transistor, a gate contact pad (not shown) may be deposited on the structures 174.

Additionally, after aligning the nanowires and disposing metal caps, an additional pair of contact pads or magnetic microelectrodes may be disposed relative to the magnetic microelectrodes 170. For example, a pair of contact pads may be disposed perpendicular to the magnetic microelectrodes 170 and nanowire structures may be aligned between the additional contact pads to form cross-bar nanowire arrangement by employing the method mentioned above with respect to FIG. 12.

Although the present technique is discussed mainly with reference to transistors, p-n and p-i-n diodes, the nanowire structure of the present technique may also be employed in other applications like switching devices, and other opto-electronic devices.

The nanowire structure and device described above find utility in a variety of electronics and opto-electronics systems, such as high-density nanowire light emitting diodes, and high-density photodetectors on flexible or rigid substrates, high-performance and large-area electronics on flexible or rigid substrate, hybrid systems with integrated electronics, such as, sensors, LED displays, and photodetector imagers on a single chip for compact display, communications, and sensor devices, and so forth. Further, the nanowire structures and devices as described above may be employed as light emitting diodes and control circuits in various display systems, such as, but not limited to wall-to-wall displays, or display on other non-flat surfaces. For example, such display device may be coupled to the insides of windshields. The nanowire devices as described above may be employed in X-ray imagers, display panels, and radio frequency identification tags. For example, such nanowire structure and devices may be employed in an X-ray imager as control circuit for the pixels and photodetector.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A nanowire structure, comprising:
a nanowire defining an axis, wherein the nanowire comprises a first end and a second end, and wherein the first end is axially spaced from the second end; and
magnetic segments coupled to the first and second ends of the nanowire.

2. The nanowire structure of claim 1, wherein the nanowire comprises a semiconductor.

3. The nanowire structure of claim 1, further comprising a shell that is coupled to the nanowire and spaced radially from the axis of the nanowire.

4. The nanowire structure of claim 3, wherein the shell comprises an oxide of a material of the nanowire.

5. The nanowire structure of claim 4, wherein the nanowire comprises silicon, and wherein the shell comprises silicon oxide.

6. The nanowire structure of claim 1, further comprising a dielectric layer coupled to the nanowire or the shell and spaced radially from the axis of the nanowire.

7. The nanowire structure of claim 1, wherein at least a portion of the nanowire is doped.

8. The nanowire structure of claim 7, wherein the nanowire includes a first doped region and a second doped region, and wherein the first and second doped regions are similarly doped.

9. The nanowire structure of claim 8, further comprising a third region, wherein the third region is disposed between the first and second regions, and wherein the third region is intrinsic or lowly doped.

10. The nanowire structure of claim 7, wherein the nanowire includes a first doped region and a second doped region, and wherein the first and second doped regions are oppositely doped.

11. The nanowire structure of claim 10, further comprising a third region disposed between the first and second regions, and wherein the third region is intrinsic or lowly doped.

12. The nanowire structure of claim 1, wherein a diameter of the nanowire is in a range from about 5 nanometers to about 1000 nanometers.

13. The nanowire structure of claim 1, wherein the magnetic segments comprise a metal, a conductive polymer, a ceramic, or combinations thereof.

14. The nanowire structure of claim 13, wherein the metal comprises nickel, cobalt, iron, or combinations thereof.

15. The nanowire structure of claim 1, wherein the magnetic segments form Ohmic contacts with the nanowire.

16. The nanowire structure of claim 1, further comprising a capping layer disposed radially around the magnetic segments.

17. A device, comprising:
a substrate;
a nanowire structure disposed on the substrate and comprising:
a nanowire defining an axis and comprising a semiconductor material, wherein the nanowire comprises a first end and a second end, wherein the first end is axially spaced from the second end;
magnetic segments coupled to the first and second ends of the nanowire; and
a first magnetic microelectrode and a second magnetic microelectrode coupled to the magnetic segments of the nanowire structure,
wherein the nanowire structure is configured to electrically couple the first and second magnetic microelectrodes, and wherein the nanowire structure is configured to be aligned in a predetermined direction under the influence of a magnetic filed.

18. The device of claim 17, further comprising a shell coupled to the nanowire and spaced radially from the axis of the nanowire, and wherein the shell comprises an oxide.

19. The device of claim 17, further comprising a first capping pad for the first magnetic microelectrode and a second capping pad for the second magnetic microelectrode disposed on the substrate such that the first and second capping pads each are coupled to the magnetic segments.

20. The device of claim 17, further comprising a third electrode disposed on the substrate and electrically insulated from the first and second magnetic microelectrodes.

21. The device of claim 20, wherein the third electrode is disposed on an undoped portion of the nanowire, and wherein the undoped portion is disposed between two doped portions of the nanowire.

22. The device of claim 17, wherein the first and second magnetic microelectrodes are disposed on the substrate, and wherein a third electrode is coupled to the nanowire structure.

23. The device of claim 17, wherein the device comprises a transistor such that the first magnetic microelectrode is a drain electrode and the second magnetic microelectrode is a source electrode.

24. The device of claim 17, wherein the magnetic field is a local magnetic filed generated between the first and second contact pads, or an external magnetic field, or both.

25. The device of claim 17, comprising a photodetector, a light emitting diode, a transistor, or combinations thereof.

26. The device of claim 17, wherein the device is employed in a radio frequency identification tag, an X-ray imager, a display device, or combinations thereof.

27. An article, comprising:
a nanoscale semiconducting pathway having a first end and a second end; and
magnetically responsive portions coupled to the first and second ends of the pathway, wherein the magnetically responsive portions are configured to align the article in response to a magnetic field.

28. A method of making a nanowire structure, comprising:
providing a substrate;
forming a porous layer on the substrate;
depositing a magnetic material layer in the pores to form first magnetic segments; and
depositing a nanowire material on the magnetic material layer to form nanowires on each of the first magnetic segments.

29. The method of claim 28, wherein the substrate comprises a semiconductor, a plastic, a flexible material, or combinations thereof.

30. The method of claim 28, wherein the step of disposing the porous layer comprises:
depositing a metal film on the substrate; and
anodizing the metal film to convert the metal film into a porous anodized metal oxide layer.

31. The method of claim 28, wherein the metal film comprises aluminum.

32. The method of claim 28, wherein the step of depositing the nanowire material comprises chemical vapor deposition.

33. The method of claim 28, further comprising depositing a dissolvable metal layer between the substrate and the metal film.

34. The method of claim 28, further comprising depositing a catalyst on the magnetic metal prior to depositing the semiconductor material on the magnetic metal to form the nanowires.

35. The method of claim 28, further comprising slicing a portion of at least one nanowire to form a nanowire having a predetermined length, wherein the slicing comprises:
depositing a photo-resist film on the nanowires; and
etching a portion of the at least one nanowire.

36. The method of claim 28, further comprising depositing second magnetic segments on each of the nanowires.

37. The method of claim 28, further comprising oxidizing the nanowires to form oxide layers on each of the nanowires to form the nanowire structures.

38. A method of making a device, comprising:
providing a substrate;
disposing a first magnetic microelectrode and a second magnetic microelectrode on the substrate;
disposing a plurality of nanowire structures between the first and second magnetic microelectrodes; and
aligning the plurality of nanowire structures, such that a majority of the nanowire structures are parallel to each other and are in operative association with the first and second magnetic microelectrodes to electrically couple the first and second magnetic microelectrodes.

39. The method of claim 38, wherein the substrate is a flexible substrate.

40. The method of claim 38, wherein the step of aligning the plurality of nanowires comprises aligning the plurality of nanowires under the influence of a magnetic field.

41. The method of claim 40, where the magnetic field is a local magnetic field between the first and second magnetic microelectrode, or external magnetic field, or both.
